(19) United States
(12) Patent Application Publication
(10) Pub. No.: US 2019/0131112 A1
(43) Pub. Date: May 2, 2019

(54) Inductively Coupled Plasma Wafer Bevel Strip Apparatus

(71) Applicant: Mattson Technology, Inc., Fremont, CA (US)

(72) Inventors: Shawming Ma, Sunnyvale, CA (US); Dixit V. Desai, Pleasanton, CA (US); Ryan M. Pakulski, Discovery Bay, CA (US)

(21) Appl. No.: 16/162,741

(22) Filed: Oct. 17, 2018

Related U.S. Application Data
(60) Provisional application No. 62/578,725, filed on Oct. 30, 2017.

(51) Int. Cl. H01J 37/32; H01L 21/687; H01L 21/68

(52) U.S. Cl. CPC H01J 37/32449; H01J 37/321; H01J 37/32642; H01J 2237/3341; H01J 37/32458; H01L 21/68742; H01L 21/68; H01J 37/32715

(57) ABSTRACT

Plasma processing apparatus for processing a bevel portion of a substrate, such as a semiconductor wafer are provided. In one example implementation, a plasma processing apparatus includes a processing chamber and a plasma chamber separated from the processing chamber by a separation grid. The apparatus includes an inductively coupled plasma source configured to generate a plasma in the plasma chamber. The apparatus includes a pedestal disposed within the processing chamber. The pedestal can be configured to support a semiconductor wafer. The separation grid can have an edge portion and a blocking portion. The edge portion can be disposed above an edge portion of the semiconductor wafer when supported on the pedestal. The edge portion of the separation grid can have a plurality of holes configured to allow the passage of active radicals generating in the plasma to the processing chamber.

### PRIORITY CLAIM

The present application is based on and claims priority to U.S. Provisional Application No. 62/578,725, titled “Inductively Coupled Plasma Wafer Bevel Strip Apparatus,” having a filing date of Oct. 30, 2017, which is incorporated by reference herein.

### FIELD

The present disclosure relates generally to apparatus, systems, and methods for processing a substrate using a plasma source.

### BACKGROUND

Plasma processing is widely used in the semiconductor industry for deposition, etching, resist removal, and related processing of semiconductor wafers and other substrates. Plasma sources (e.g., microwave, ECR, inductive, etc.) are often used for plasma processing to produce high density plasma and reactive species for processing substrates. Plasma processing tools can be used for wafer bevel or wafer edge etch applications. For instance, polymer and/or other materials deposited on the bevel portion of the wafer (e.g., a slanted portion at the wafer edge) during, for instance, other treatment processes (e.g., wafer etch process) can be removed using a bevel etch process. Bevel etch plasma processes have required direct plasma exposure induced ion bombardment.

### SUMMARY

Aspects and advantages of embodiments of the present disclosure will be set forth in part in the following description, or may be learned from the description, or may be learned through practice of the embodiments.

One example aspect of the present disclosure is directed to a plasma processing apparatus for processing a bevel portion of a semiconductor wafer. The plasma processing apparatus includes a processing chamber. The plasma processing apparatus includes a plasma chamber separated from the processing chamber by a separation grid. The plasma processing apparatus includes an inductively coupled plasma source configured to generate a plasma in the plasma chamber. The plasma processing apparatus includes a pedestal disposed within the processing chamber. The pedestal can be configured to support a semiconductor wafer. The separation grid can have an edge portion and a blocking portion. The edge portion can be disposed above an edge portion of the semiconductor wafer when the semiconductor wafer is supported in the pedestal. The edge portion of the separation grid can have a plurality of holes configured to allow the passage of active radicals generated in the plasma to the processing chamber (e.g., to provide for the treatment of the bevel portion of the semiconductor wafer). In some embodiments, the blocking portion can reduce the passage of ions and active radicals generated in the plasma to the processing chamber.

Other example aspects of the present disclosure are directed to systems, methods, and apparatus for processing a bevel portion of a semiconductor wafer.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a bevel portion of a semiconductor wafer;

FIG. 2 depicts a plasma processing apparatus according to example embodiments of the present disclosure;

FIGS. 3(a), 3(b), 3(c), and 3(d) depict example inserts that can be used in a plasma processing apparatus according to example embodiments of the present disclosure;

FIG. 4 depicts a cross-sectional view of an example separation grid according to example embodiments of the present disclosure;

FIG. 5 depicts a plan view of an example separation grid according to example embodiments of the present disclosure;

FIG. 6 depicts a close up view of treating a bevel portion of a semiconductor wafer using a plasma processing apparatus according to example embodiments of the present disclosure;

FIG. 7 depicts a movable pedestal for adjusting a vertical position of a semiconductor wafer in a plasma processing apparatus during bevel treatment processes according to example embodiments of the present disclosure;

FIG. 8 depicts a movable lift pin assembly for adjusting a vertical position of a semiconductor wafer in a plasma processing apparatus according to example embodiments of the present disclosure;

FIG. 9 depicts a focus ring for alignment of a semiconductor wafer according to example embodiments of the present disclosure; and

FIG. 10 depicts a flow diagram of an example method for treating a bevel portion of a semiconductor wafer according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

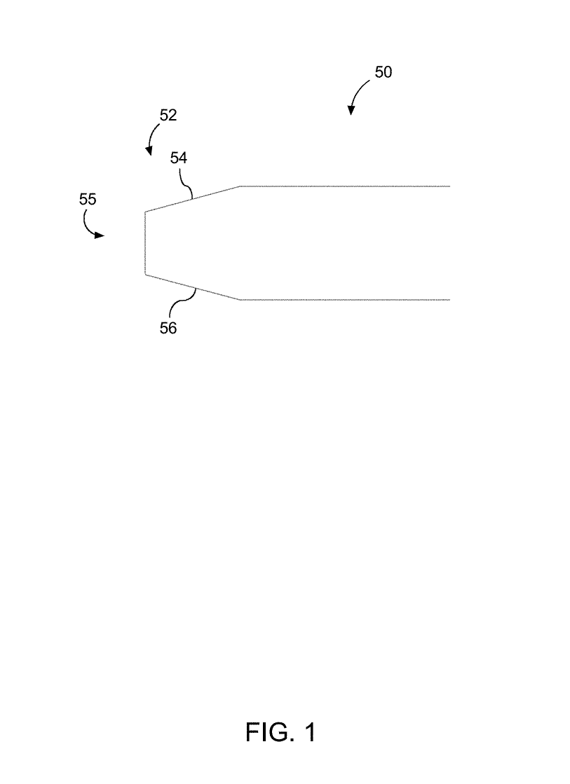

Example aspects of the present disclosure are directed to plasma processing apparatus for processing of a bevel portion of a substrate, such as a semiconductor wafer. FIG. 1 depicts an example bevel portion 55 of a semiconductor wafer 50. As shown the bevel portion 55 is located at an edge portion 52 of the wafer 50. The bevel portion 55 can include a front side surface 54 and a back side surface 56. The front side surface 54 and/or the back side surface 56 of the bevel portion 55 can be a slanted surface. Bevel plasma processes can be used to remove materials (e.g., polymer, photoresist residue, silicon oxide film, silicon nitride film, metal films such as TiN, TaN, etc.) from the bevel portion 55 of the semiconductor wafer 50.

Bevel plasma processes to remove polymer and/or other materials from a bevel portion of a wafer have required the use of direct plasma exposure induced ion bombardment. Direct plasma exposure induced ion bombardment can lead to wafer damage and/or damage to nearby devices formed on the wafer due to plasma non-uniformities. Direct plasma exposure at the wafer edge can also cause strong UV exposure, which can harden any carbon containing films on the bevel portion, making the films more difficult to remove.

A bevel etch apparatus using direct plasma exposure can require high precision wafer placement to ensure proper exposure width on the wafer backside for azimuthal symmetry. As an example, in some applications, the error range for wafer placement can be less than 0.1 mm, making for very expensive wafer placement mechanisms (e.g., robot for wafer placement). A bevel etch apparatus using direct plasma exposure can require plasma source power, bias power, and a high temperature electrostatic chuck. This can increase the cost of the tool and product costs.

A bevel etch apparatus using direct plasma exposure can pose other challenges. For example, direct plasma exposure can serve as background light. This can make optical endpoint detection difficult. As another example, bevel etch apparatus can use side pumping ports for process gas. This can make azimuthal uniformity of the plasma processing difficult to achieve.

Plasma strip tools (e.g., plasma ashers) have been used for processing a bevel portion of a semiconductor wafer. These tools can use lift pins to remove polymer and other materials from both the front side and the back side of the bevel portion of the wafer. Use of lift pins can remove the wafer from contact with a pedestal heat source and thus can limit the high ends of temperature control during processing.

Example aspects of the present disclosure are directed to an inductively coupled plasma strip apparatus that can be used for plasma processing of a bevel portion of a wafer using active radicals generated using a remote plasma source without any direct plasma exposure. More particularly, the plasma strip apparatus can provide for the plasma processing of the bevel portion of a wafer using active radicals (e.g. neutrals) generated using a remote plasma source with reduced direct ion bombardment on the wafer edge and/or reduced plasma sheath formation on the wafer surface.

In some embodiments, the plasma strip apparatus can include a processing chamber and a plasma chamber. The plasma chamber can be separate from the processing chamber. A separation grid can separate the plasma chamber from the processing chamber. The processing chamber can include a pedestal for supporting a wafer during processing. A plasma can be generated in the plasma chamber using an inductively coupled plasma source.

According to example embodiments of the present disclosure, the separation grid can include an edge portion and a blocking portion. The edge portion can be positioned over an edge portion of a semiconductor wafer when the wafer is positioned on the pedestal in the processing chamber. The edge portion can include a plurality of holes. The holes can filter UV light and/or ions generated in the plasma but can allow the passage of active radicals for treatment of a bevel portion of a semiconductor wafer.

The size of the edge portion of the separation grid can correspond to a size of a bevel portion at the edge of a semiconductor wafer. For instance, the edge portion can extend a distance from a perimeter of the separation grid towards the center of the separation grid of about 30 mm or less, such as about 15 mm or less, such as about 10 mm or less, such as about 5 mm or less, such as about 5 mm or less, such as about 3 mm or less. In some embodiments, the plurality of holes in the separation grid can overlap the bevel portion of the semiconductor wafer by about 20% of the size of the bevel portion on each side of the bevel portion, such as by about 10% on each side of the bevel portion.

The blocking portion can be positioned over the remainder of the semiconductor wafer (e.g., the portion of the wafer with devices). The blocking portion can be configured to block both ions and active radicals from passing through to the processing chamber, protecting the remainder of the semiconductor wafer (e.g., the device portion of the semiconductor wafer) from damage during processing of a bevel portion of the semiconductor wafer. In some embodiments, the blocking portion can be a solid portion of the separation grid. In some embodiments, the blocking portion can include no holes for passage of neutral radicals or ions.

In some embodiments, the separation grid can include a gas injection aperture. The gas injection aperture can provide for the injection of a protective gas onto the surface of the wafer during processing of the bevel portion. The gas can serve as a shield to prevent active radicals passing through the edge portion of the separation grid from interacting with the remainder of the semiconductor wafer (e.g., the device portion of the semiconductor wafer). In some embodiments, the gas injection can be controlled to adjust a width of the bevel treatment process on the substrate by controlling the width of the gas curtain. The gas can be an neutral gas, such as N₂, He, Ar, etc.

In some embodiments, the separation grid can be a multi-plate grid (e.g., a dual grid) having a first grid plate and a second grid plate in spaced parallel relation. The separation grid can include additional parallel plates without deviating from the scope of the present disclosure. Holes in the first grid plate can be offset relative to holes in the second grid plate to reduce UV light passing through the edge portion of the separation grid. This can reduce UV hardening of polymer deposited on a bevel portion of the wafer, leading to improved processing of the bevel portion of the wafer. In addition, the reduction of UV light can provide for better optical endpoint control using optical emission spectrums generated during the processing of the bevel portion of the wafer.

In some embodiments, the plasma processing apparatus can include an insert disposed in the plasma chamber. The insert can include a peripheral portion and a center portion. The center portion can extend vertically past the peripheral portion. In some embodiments, the center portion can extend all the way to the separation grid. In some embodiments, the center portion can be connected to the separation grid. This can assist with focusing radicals generated in the plasma above the bevel portion of the wafer and/or the edge portion of the separation grid. In addition, a conductive metal included as part of the center portion of the insert can facilitate cooling of the inductively coupled plasma source. In some embodiments, the insert can define a gas channel to allow the passage of gas from a gas source to the gas injection aperture of the separation grid.

In some embodiments, the plasma processing apparatus can include a movable pedestal that is movable in a vertical direction. The pedestal can be moved during processing to adjust a vertical position of a wafer during processing. The bevel portion of the wafer can extend over the surface of the pedestal to allow for processing. Because the wafer remains on the pedestal, the temperature of the wafer can be more easily controlled.

In some embodiments, a linear lift pin control assembly can be used to further adjust the vertical position of the wafer relative to the separation grid. This can provide for a high temperature control range (e.g., by providing the capability to remove the wafer from the heat source) as well distance between separation grid and wafer as process control parameters.

In some embodiments, concentric gas chamber pumping can be provided at the bottom of the processing chamber. This can facilitate azimuthal uniformity of plasma processing of the bevel portion of the wafer according to example aspects of the present disclosure. In addition, the gas pumping can pull radicals toward a bottom surface of a bevel portion of the wafer so that the bottom surface of the bevel portion can be treated according to example embodiments of the present disclosure.

In some embodiments, the plasma processing apparatus can include an aligning focus ring to facilitate wafer placement in the processing chamber for processing the bevel portion of the wafer. The focus ring can facilitate having a symmetrical overhang of a bevel portion of the wafer relative to the pedestal to reduce the stringent requirement of expensive wafer placement mechanism (e.g., robots) for placement of a wafer for uniform bevel processing.

The apparatus, systems, and methods according to example embodiments of the present disclosure provide a number of technical effects and benefits. For instance, the plasma processing apparatus can have much lower cost relative to certain bevel etch apparatus because no electrostatic chuck is required to hold the substrate during processing. Moreover, no RF bias power is involved, meaning only one RF power source is required. In addition, in some embodiments, strict requirements for wafer placement system (e.g., robots) can be reduced.

In some embodiments, a plasma strip tool can be retrofitted for processing a bevel portion of a semiconductor wafer according to example embodiments of the present disclosure. More particularly, the separation grid and/or insert of a plasma strip tool can be changed out with the separation grid and/or insert according to example aspects of the present disclosure to easily adapt the plasma strip tool for processing a bevel portion of a semiconductor wafer according to the embodiments disclosed herein.

One example aspect of the present disclosure is directed to a plasma processing apparatus for processing a bevel portion of a semiconductor wafer. The plasma processing apparatus includes a processing chamber. The plasma processing apparatus includes a plasma chamber separated from the processing chamber by a separation grid. The plasma processing apparatus includes an inductively coupled plasma source configured to generate a plasma in the plasma chamber. The plasma processing apparatus includes a pedestal disposed within the processing chamber. The pedestal is configured to support a semiconductor wafer. The separation grid has an edge portion and a blocking portion. The edge portion is disposed above an edge portion of the semiconductor wafer when supported on the pedestal. The edge portion of the separation grid has a plurality of holes configured to allow passage of active radicals generated in the plasma to the processing chamber.

In some embodiments, the active radicals provide for treatment of a bevel portion of the semiconductor wafer. The blocking portion reduces passage of ions and active radicals generated in the plasma to the processing chamber. For instance, in some embodiments, the blocking portion is a solid portion of the separation grid. The edge portion can filter one or more ions generated in the plasma. In some embodiments, the edge portion extends a distance of about 30 mm or less from a perimeter of the separation grid.

In some embodiments, the separation grid includes a first grid plate and a second grid plate in spaced parallel relation with one another. The separation grid can filter UV light.

In some embodiments, the separation grid can have a gas injection aperture formed in a center portion of the separation grid. The gas injection aperture can be configured to allow the injection of a protective gas onto the wafer to control a width of a bevel treatment process on the semiconductor wafer.

In some embodiments, the apparatus can include an insert. The insert can have a peripheral portion and a center portion. The center portion can extend a vertical distance past the peripheral portion. The center portion can extend to the separation grid. The plasma processing apparatus can have a first gas injection port to the plasma chamber and a second gas injection port for providing gas through the insert. The insert can define a gas channel from the second gas injection port to the gas injection aperture on the separation grid.

In some embodiments, the apparatus can include an aligning focus ring configured to assist positioning of the wafer on the pedestal. In some embodiments, the pedestal comprises a heat source for heating the wafer. In some embodiments, the pedestal is movable in a vertical direction to adjust a vertical position of the wafer relative to the separation grid. In some embodiments, the apparatus includes one or more movable lift pins configured to support the wafer. The lift pins can be moveable in a vertical direction to adjust a vertical position of the wafer relative to the separation grid.

Another example aspect of the present disclosure is directed to a separation grid for a plasma processing apparatus having a processing chamber and a plasma chamber remote from the processing chamber. The separation grid has an edge portion and a blocking portion. The edge portion has a plurality of holes configured to allow the passage of active radicals generated in the plasma to the processing chamber to treat the edge portion of the semiconductor wafer.

In some embodiments, the blocking portion reduces the passage of ions and active radicals generated in the plasma to the plasma chamber. In some embodiments, the blocking portion does not have any holes. In some embodiments, the blocking portion is a solid portion. In some embodiments, the edge portion filters one or more ions generated in the plasma. In some embodiments, the edge portion extends a distance of about 30 mm or less from a perimeter of the separation grid.

In some embodiments, the separation grid is a dual grid having a first grid plate and a second grid plate in spaced parallel relation with one another. In some embodiments, the separation grid filters UV light.

In some embodiments, the separation grid has a gas injection aperture formed in a center portion of the separation grid. The gas injection aperture configured to allow the injection of a protective neutral gas onto the semiconductor wafer to control a width of a bevel treatment process on the semiconductor wafer.

Another example embodiment of the present disclosure is directed to an insert for a plasma chamber in a plasma processing apparatus. The plasma chamber can be separated from the processing chamber by a separation grid. The insert can have a peripheral portion and a center portion. The center portion can extend a vertical distance past the peripheral portion. The center portion can define a gas channel for passage of gas from a gas injection port. In some embodiments, the gas channel is configured to provide gas from the insert to a gas injection aperture defined in a center portion of the separation grid.

Another example embodiment of the present disclosure is directed to a plasma processing apparatus for processing a bevel portion of a semiconductor wafer. The plasma processing apparatus includes a processing chamber. The plasma processing apparatus includes a plasma chamber. The plasma processing apparatus includes an inductively coupled plasma source configured to generate a plasma in the plasma chamber. The plasma processing apparatus includes a pedestal disposed within the processing chamber. The pedestal is configured to support a semiconductor wafer. The apparatus includes a separation grid separating the plasma chamber from the processing chamber. The separation grid has a first grid plate and a second grid plate in spaced parallel relationship. The separation grid has an edge portion and a blocking portion. The edge portion is disposed above t an edge portion of the semiconductor wafer when supported on the pedestal. The edge portion has a plurality of holes configured to allow the passage of active radicals generated in the plasma to the processing chamber. The separation grid further includes a gas injection aperture disposed in a center portion of the separation grid. The apparatus includes an insert disposed in the processing chamber. The insert has peripheral portion and a center portion. The center portion extends vertically past the peripheral portion to the separation grid. The insert defines a gas channel for providing gas from a gas injection port to the gas injection aperture of the separation grid.

Another example aspect of the present disclosure is directed to a method of treating a bevel portion of a semiconductor wafer in a plasma processing apparatus. The method includes placing a semiconductor wafer having a bevel portion on a pedestal in a processing chamber of a plasma processing apparatus, the processing chamber being separated from a plasma chamber by a separation grid, the separation grid having an edge portion disposed over the edge of the semiconductor wafer and a center portion; heating the semiconductor wafer using one or more heat sources in the pedestal; generating a plasma in the plasma chamber by energizing an inductively coupled plasma source; filtering one or more ions in the edge portion of the separation grid; providing active radicals through edge portion to treat the bevel portion of the semiconductor wafer; and blocking ions and active radicals generated in the plasma with the blocking portion of the separation grid. In some embodiments, the method includes providing a gas through a gas injection aperture of the separation grid to a control a width of the bevel treatment process on the semiconductor wafer.

Example aspects of the present disclosure are discussed with reference to treating a bevel portion of a semiconductor wafer for purposes of illustration and discussion. Those of ordinary skill in the art, using the disclosures provided herein, will understand that aspects of the present disclosure can be used in conjunction with the processing of other workpieces without deviating from the scope of the present disclosure. As used herein, the use of the term “about” in conjunction with a numerical value can refer to within 20% of the stated numerical value.

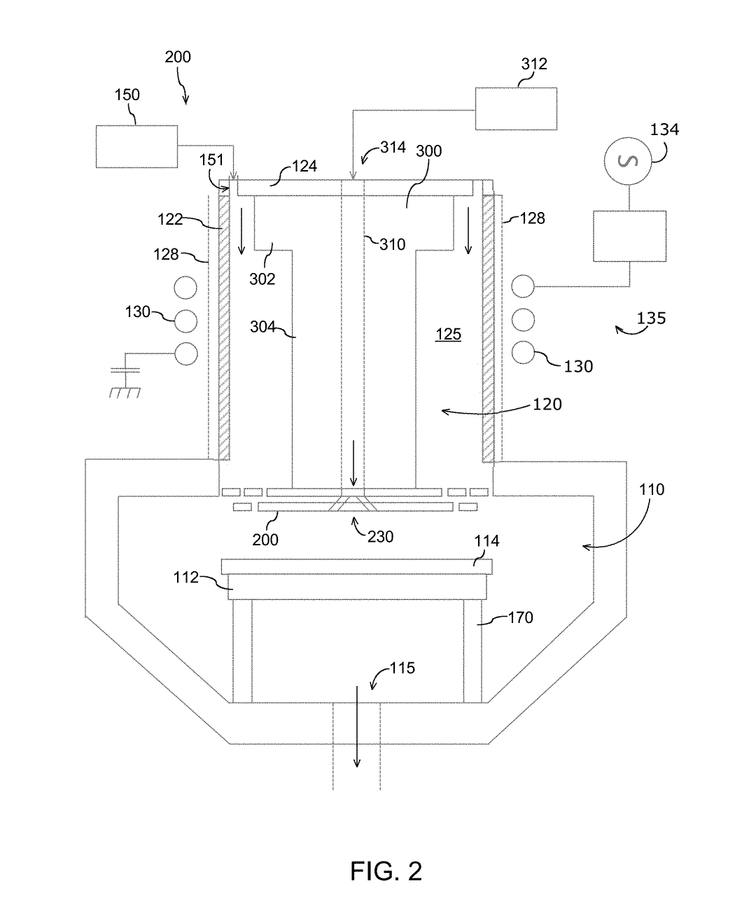

FIG. 2 depicts an example plasma processing apparatus 100 that can be used to perform bevel treatment processes according to example embodiments of the present disclosure. As illustrated, plasma processing apparatus 100 includes a processing chamber 110 and a plasma chamber 120 that is separate from the processing chamber 110. Processing chamber 110 includes a substrate holder or pedestal 112 operable to hold a workpiece 114 to be processed, such as a semiconductor wafer. In this example illustration, a plasma is generated in plasma chamber 120 (i.e., plasma generation region) by an inductively coupled plasma source 135 and desired particles are channeled from the plasma chamber 120 to the surface of wafer 114 through a separation grid assembly 200. The pedestal 112 is not required to have RF bias. The pedestal 112 is not required to have an electrostatic chuck to clamp the wafer 114. The pedestal 112 can include a heat source (e.g., one or more electric heaters) to heat the wafer 114.

The plasma chamber 120 includes a dielectric side wall 122 and a ceiling 124. The dielectric side wall 122, ceiling 124, and grid 200 define a plasma chamber interior 125. Dielectric side wall 122 can be formed from any dielectric material, such as quartz. The inductively coupled plasma source 135 can include an induction coil 130 disposed adjacent the dielectric side wall 122 about the plasma chamber 120. The induction coil 130 is coupled to an RF power generator 134 through a suitable matching network 132. Reactant and carrier gases can be provided to the chamber interior 125 from gas supply 150 and annular gas distribution channel 151 or other suitable gas introduction mechanism. When the induction coil 130 is energized with RF power from the RF power generator 134, a plasma can be generated in the plasma chamber 120. In a particular embodiment, the plasma processing apparatus 128 can include an optional faraday shield 128 to reduce capacitive coupling of the induction coil 130 to the plasma.

As shown in FIG. 2, the plasma processing apparatus can further include a concentric pumping chamber bottom 115 in the processing chamber 110. The concentric pumping chamber bottom 115 can be used to more uniformly control the pumping of gas from the processing chamber 110 to provide for increased azimuthal uniformity.

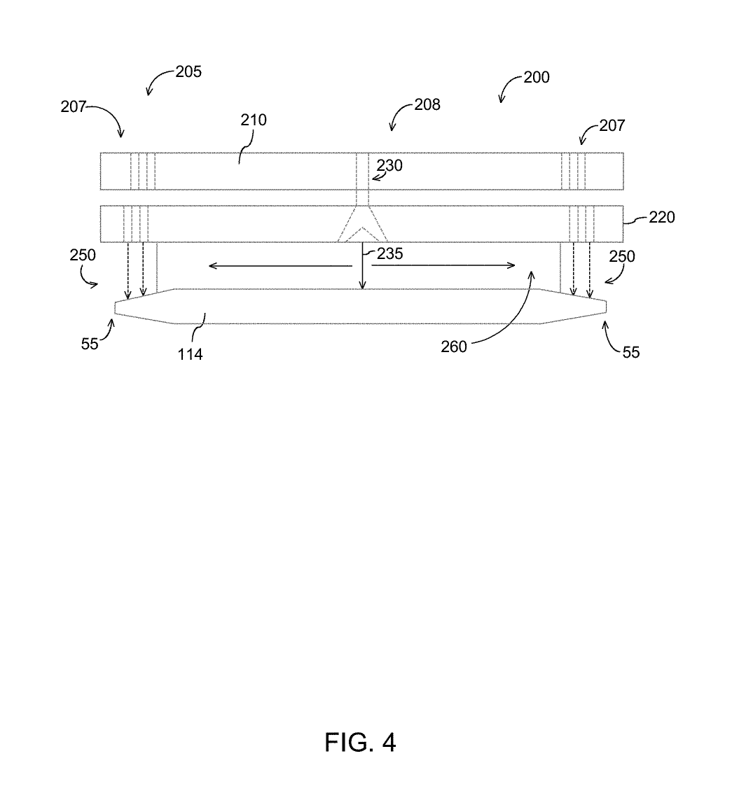

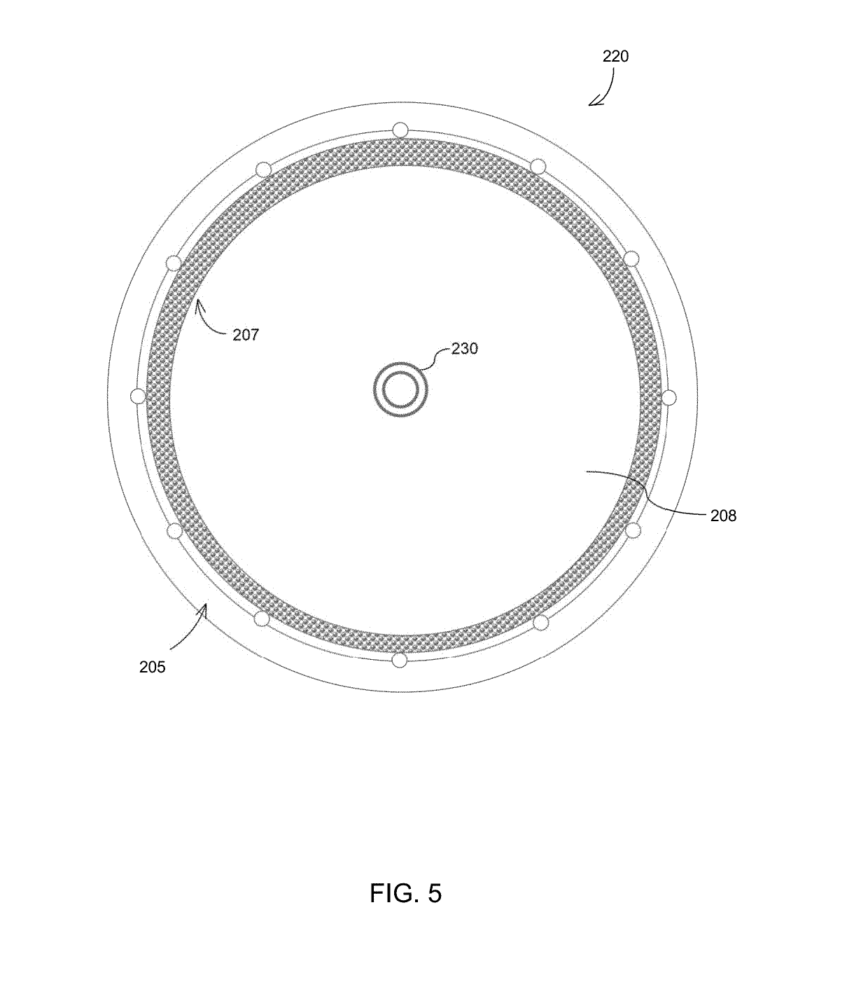

Referring to FIG. 2, the separation grid assembly 200 separates the plasma chamber 120 from the processing chamber 110. Details concerning the separation grid assembly 200 are discussed in more detail with respect to FIGS. 4, 5 and 6.

The plasma processing apparatus 100 can include an insert 300 in the plasma chamber 120. The insert 300 can be a stepped insert having a peripheral portion 302 and a center portion 304. The center portion 304 of the insert can extend vertically past the center portion 302. As shown, in FIG. 2, the center portion 304 can extend to the separation grid 200. In some embodiments, the center portion 304 can be connected to the separation grid 200.

The insert 300 can be removably inserted into plasma chamber 120 or can be a fixed part of plasma chamber 120. The insert 300 can define a gas injection channel proximate the side wall 122 of the plasma chamber 120. The gas injection channel can feed process gas into the chamber interior 125 proximate the induction coil 130 and into an active region defined by the insert 300 and side wall 120. The active region can provide a confined region within plasma chamber interior 125 for active heating of electrons. The narrow gas injection channel can prevent plasma spreading from the chamber interior 125 into the gas channel. The insert 300 the process gas to be passed through the active region where electrons are actively heated. The insert 300 can also assist with focusing active neutrals to the edge portion 205 of the separation grid 200 by confining the active neutrals to an area proximate the edge portion 205.

In some embodiments, the insert 300 can be made from an aluminum material with a coating configured to reduce surface recombination. In some embodiments, the insert 300 can be a quartz material or insulative material. In some embodiments 300 the insert 300 can include a metal material.

In some embodiments, the insert 300 can include gas injection port 314 for receiving a gas from a gas source 312. The gas can pass through a channel 310 defined in the center portion of the insert 300. The gas can be provided to a gas injection aperture 230 in the center portion of the separation grid 200 to form a protective gas curtain on a surface of the semiconductor wafer 114 to control a width of a bevel treatment process according to example embodiments of the present disclosure as will be discussed in more detail below.

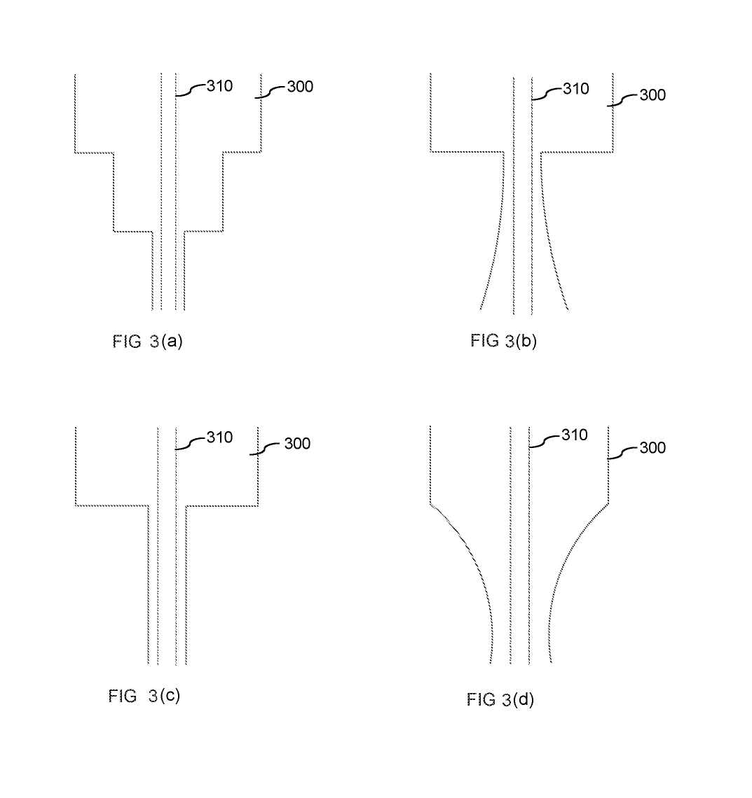

The insert 300 can have different shapes without deviating from the scope of the present disclosure. For example, FIGS. 3(a), 3(b), 3(c), and 3(d) depict inserts 300 with differing shapes according to example embodiments of the present disclosure. In FIG. 3(a), the insert 300 has a narrower central portion. A gas channel 310 passes through the central portion of the insert 300. In FIG. 3(b), the insert 300 includes a central portion with surfaces that curve outwards as the central portion extends away from the peripheral portion of the insert 300 and/or toward the separation gird. A gas channel 310 passed through insert 300. In FIG. 3(c), the insert 300 includes a very narrow central portion. In some embodiments, the very narrow central portion can be and/or can correspond to the gas injection channel 310 passing through the insert. In FIG. 3(d), the insert 300 includes a central portion with surfaces that curve inwards as the central portion extends away from the peripheral portion of the insert 300 and/or toward the separation grid.

Referring to FIGS. 4, 5, and 6, details concerning an example separation grid 200 will be set forth. The separation grid 200 has an edge portion 205 and a blocking portion 208. The edge portion 205 can include a plurality of holes 207. The holes 207 can block the passage of ions through the separation grid 200 but can allow the passage of neutral radicals and/or other neutral particles. More particularly, charged particles can recombine on the walls in their path through the holes 207. Neutral radicals and/or other neutral particles can flow more freely through the holes 207.

The blocking portion 208 can be configured to block both neutral radicals and ions and other particles. In some embodiments, the blocking portion 208 can be a solid portion of the separation grid (e.g., a portion with little or no holes). For instance, the blocking portion 208 can be a solid metal portion that completely or near completely blocks ions, neutral radicals, and other particles generated in the plasma.

In some embodiments, the size of the edge portion 205 can be configured such that the edge portion 205 with the plurality of holes 207 overlaps a bevel portion 55 of a semiconductor wafer 114 when the semiconductor wafer 114 is located on the pedestal 112. In this way, neutral radicals 250 passing through the holes 207 can be used to remove materials from the bevel portion 55 of the semiconductor wafer 114. In some embodiments, the size of the edge portion 205 can extend, for instance, a distance of about 15 mm or less, from a perimeter of the separation grid 200, such as about 10 mm or less, such as about 5 mm or less, such as about 3 mm or less.

As shown in FIG. 3, the separation grid assembly 200 can be a multi-plate separation grid (e.g., a dual grid, a three plate grid, a four plate grid, etc.). For instance, the separation grid assembly 200 can include a first grid plate 210 and a second grid plate 220 that are spaced apart in parallel relationship to one another. The first grid plate 210 and the second grid plate 220 can be separated by a distance.

The first grid plate 210 can have a first grid pattern having a plurality of holes 207 in the edge portion 205 of the separation grid 200. The second grid plate 220 can have a second grid pattern having a plurality of holes 207 in the edge portion 205 of the separation grid 200. The first grid pattern can be the same as or different from the second grid pattern. Charged particles can recombine on the walls in their path through the holes of each grid plate 210, 220 in the separation grid 200. Neutral radicals and other neutral particles can flow relatively freely through the holes 207 in the first grid plate 210 and the second grid plate 220. The solid portion 208 can extend between the edge portion 205 with holes 207 to the center of the separation grid 200 such that little to no holes exist between the edge portion 205 and the center of the separation grid 200.

In some embodiments, the holes 207 in the first grid plate 210 and the second grid plate 220 can be offset from one another to reduce the passage of UV light through the separation grid 200. This can prevent hardening of carbon-containing materials on the bevel portion of the semiconductor wafer 114, facilitating removal of such materials from the bevel portion of the semiconductor wafer 114.

In some embodiments, the first grid plate 210 can be made of metal (e.g., aluminum) or other electrically conductive material and/or the second grid plate 220 can be made from either an electrically conductive material or dielectric material (e.g., quartz, ceramic, etc.). In some embodiments, the first grid plate 210 and/or the second grid plate 220 can be made of other materials, such as silicon or silicon carbide. In the event a grid plate is made of metal or other electrically conductive material, the grid plate can be grounded.

In some embodiments, the separation grid 200 can include a gas injection aperture 230 located in a center portion of the separation grid 200. The gas injection aperture 230 can be used to inject a neutral gas 235 (e.g., N₂, He, Ar, etc.) from a gas source onto a surface of a semiconductor wafer 114. The gas 235 can form a gas curtain 260 that can prevent radicals 250 passing through the holes 207 in the edge portion 205 of the separation grid 200 from damaging other aspects of the wafer 114, such as devices formed on the wafer 114. Parameters associated with the gas flow (e.g., flow rate, etc.) can be controlled to control the width of the gas curtain 260. In this way, the gas injection aperture 230 can allow the injection of a protective gas onto the wafer 114 to control a width of a bevel treatment process on the wafer 114.

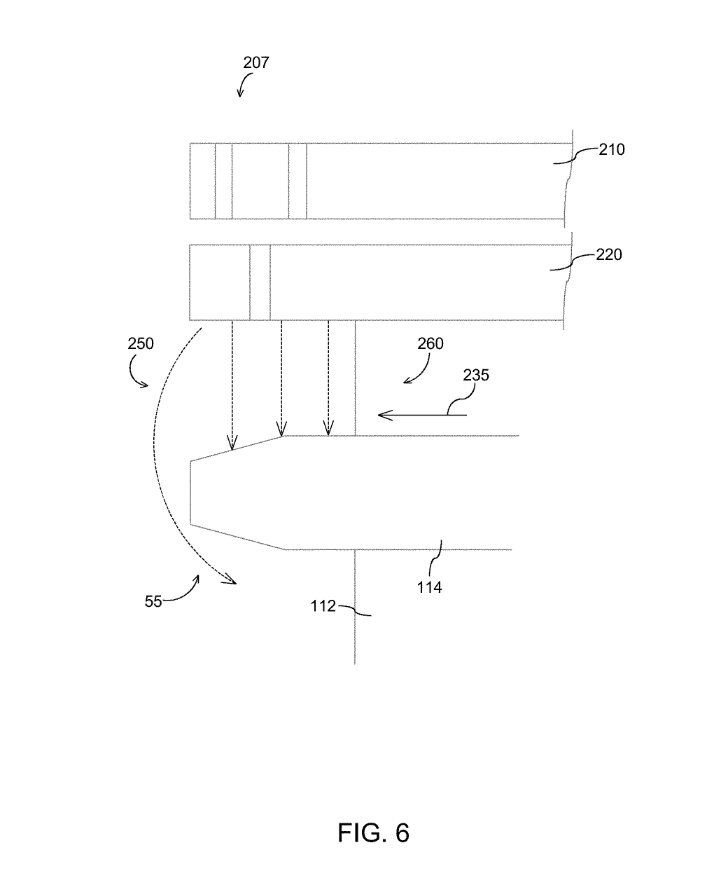

As shown in FIG. 6, the pedestal 112 can provide a boundary on the back surface of the bevel portion 55 for bevel processing according to example embodiments of the present disclosure. More particularly, the pedestal 112 can shield portions of the substrate 114 from exposure to the neutral radicals 250 or other particles that are used to treat a back surface of the bevel portion 55.

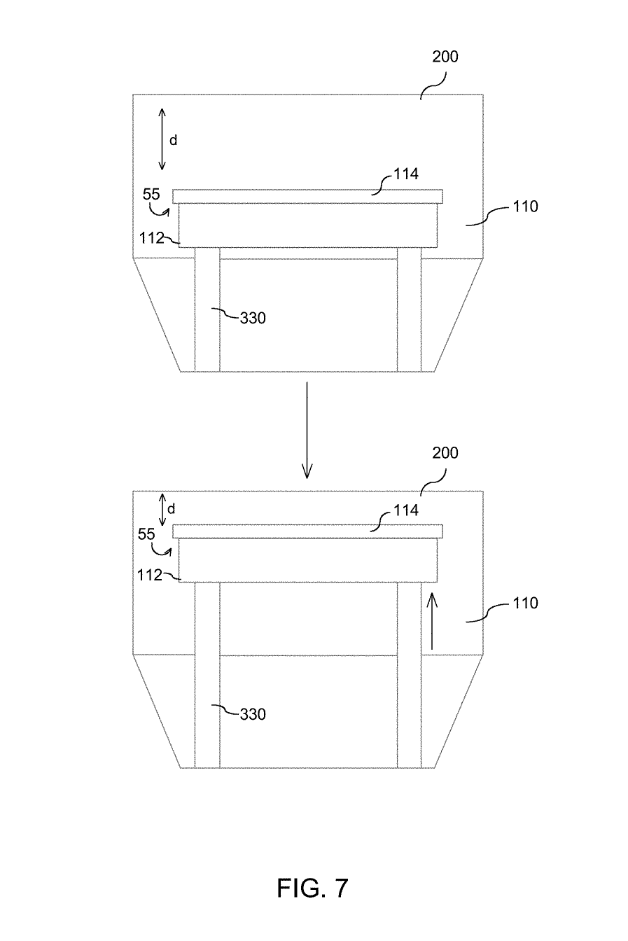

As shown in FIG. 7, in some embodiments, the plasma processing apparatus 100 can include a movable pedestal 112. The pedestal 112 can be coupled to a pedestal movement mechanism 330. The pedestal movement mechanism 330 can include one or more pneumatic, hydraulic, mechanical, robotic, or other suitable devices to move the pedestal 112 in a vertical direction in the processing chamber 110. In this way, the vertical position of the pedestal 112 can be moved to adjust a distance d between a wafer 114 and the separation grid 200.

In this example embodiment, the vertical distance d between the separation grid 200 and the wafer 114 can be adjusted as a process parameter for a bevel treatment process according to example aspects of the present disclosure. The temperature of the wafer 114 can be more tightly controlled as the majority of the wafer 114 remains in contact with the pedestal 112, which can include a heat source for heating the wafer 114. In some embodiments, the bevel portion 55 of the wafer 114 can overhang an edge of the pedestal to allow for treatment of both the front side surface and the back side surface of the bevel portion 55 of the wafer 114.

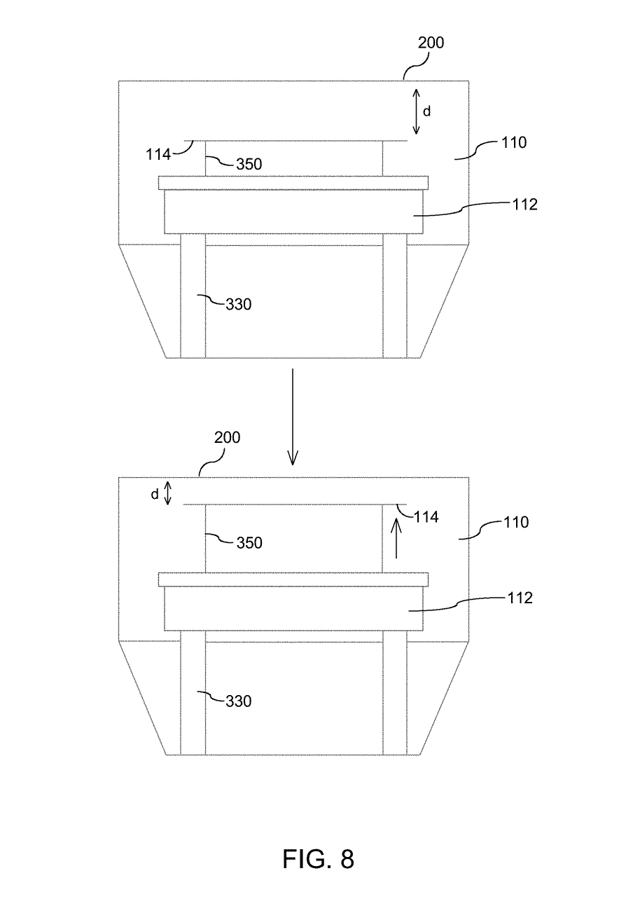

In addition and/or in the alternative, as shown in FIG. 8, the plasma processing apparatus can be configured to support the wafer 114 during processing using one or more lift pins 350. The lift pins 350 can be coupled to a lift pin assembly that can move the lift pins 350 in a vertical direction. In this way, a vertical position of the lift pins 350 can be moved to adjust a distance d between the wafer 114 and the separation grid 200 as a process parameter for a bevel treatment process according to example embodiments of the present disclosure. In some embodiments, the lift pin mechanism can be controlled using a (e.g. a linear drive) to impart linear motion to the lift pins 350 in a vertical direction.

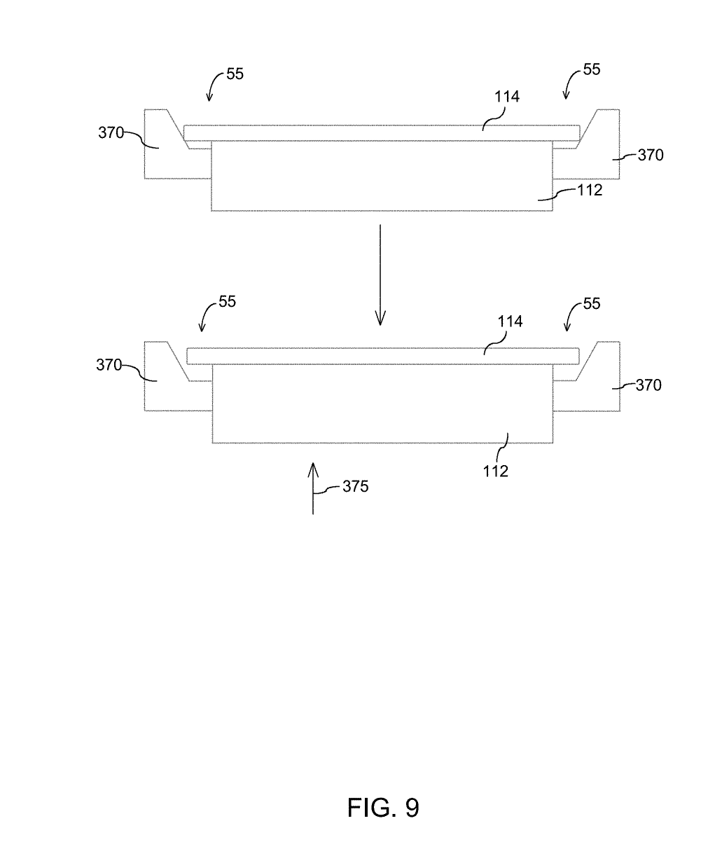

In some embodiments, as shown in FIG. 9, the plasma processing apparatus according to example aspects of the present disclosure can include an aligning focus ring to facilitate placement of a semiconductor wafer on a pedestal for bevel treatment processing according to example embodiments of the present disclosure. For instance, FIG. 9 depicts an aligning focus ring 370 placed around a pedestal 112. The aligning focus ring 350 can have a cavity 375 that can facilitate positioning of a wafer 114 with azimuthal symmetry on the pedestal 112. Once the wafer 114 is positioned, the pedestal can be moved in a vertical direction 375 closer to the separation grid for bevel treatment processing according to example embodiments of the present disclosure. As shown in FIG. 9, the bevel portion 55 of the substrate 114 can have symmetrical overhang relative to the pedestal 112 about the azimuth of the substrate 114.

Other suitable components can be used to align the wafer 114 for bevel processing without deviating from the scope of the present disclosure. For instance, one or more finger mechanisms instead of a ring can be used to align the wafer 114 for bevel processing.

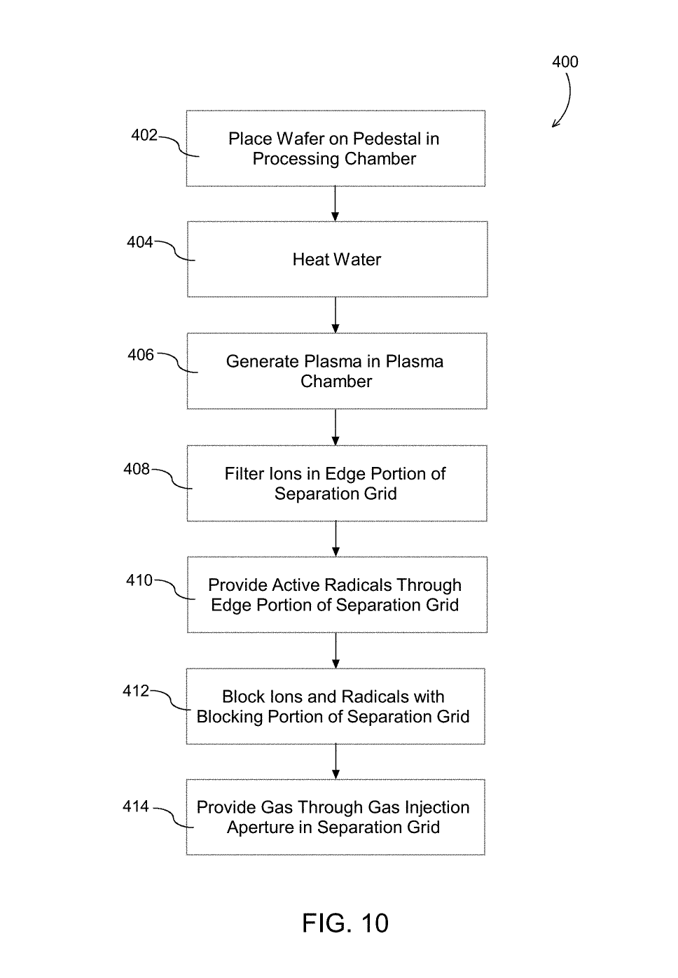

FIG. 10 depicts a flow diagram of an example method (400) according to example embodiments of the present disclosure. The method (400) can be implemented, for instance, using the plasma processing apparatus 100 of FIG. 2. FIG. 10 depicts steps performed in a particular order for purposes of illustration and discussion. Those of ordinary skill in the art, using the disclosures provided herein, will understand that the various steps or operations of any of the methods described herein can be adapted, expanded, include steps not illustrated, performed simultaneously, rearranged, omitted, and/or modified in various ways without deviating from the scope of the present disclosure.

At (402), the method can include placing a wafer on a pedestal in a processing chamber. For instance, a semiconductor wafer 114 can be placed on a pedestal 112 in the processing cashmere 110. The semiconductor wafer can then be heated for bevel treatment processing as shown at (404). For instance, one or more heat sources in the pedestal 112 can be used to heat the semiconductor wafer 114.

At (406), the method can include generating a plasma in a plasma chamber. The plasma chamber can be remote from the processing chamber. The plasma chamber can be separated from the processing chamber with a separation grid. The plasma can be generated by energizing an induction coil proximate the processing chamber with RF energy to generate a plasma using a process gas admitted into the plasma chamber.

For instance, process gas can be admitted into the plasma chamber 120 from a gas source 150. RF energy from RF source 134 can be applied to induction coil 130 to generate a plasma in the plasma chamber 120. In this way, a plasma can be generated in the plasma source 120 using the inductively coupled plasma source 135.

At (408), the method can include filtering ions generated in the plasma using an edge portion of the separation grid. As discussed above, the edge portion 205 of the separation grid 200 can include a plurality of holes 207. The holes 207 can prevent the passage of ions generated in the plasma from passing from the plasma chamber 120 to the processing chamber 110. The holes 207 can also be used to reduce UV light from entering the processing chamber 110 from the plasma chamber 120.

At (410), the method can include providing active radicals through the edge portion of the separation grid. For instance, edge portion 205 of the separation grid 200 can include holes 207 that allow for the passage of active radicals generated in the plasma through the edge portion 205 of the separation grid 200 to remove material from a bevel portion 55 of a semiconductor wafer 114.

At (412), the method can include blocking ions and active radicals generated in the plasma with a blocking portion of the separation grid. For instance, a blocking portion 208 of the separation grid 200 can be a solid portion with little to no holes that prevent the passage of both ions and active radicals generated in the plasma. As a result, portions of the semiconductor wafer 114 not including the bevel portion 55 (e.g., the device portion of the semiconductor wafer) can be protected from damage.

At (414), the method can include providing a gas (e.g., neutral gas) through a gas injection aperture in the separation grid. For instance, neutral gas can be provided onto the surface of the semiconductor wafer 114 via a gas injection aperture 130 in a center portion of the separation grid 200. The gas can form a protective gas curtain on the surface of the semiconductor wafer 114 to prevent active radicals passing through the edge portion 205 of the separation grid 200 from damaging the remainder of the semiconductor wafer 114. In this way, a width of the bevel treatment process can be controlled using one or more parameters associated with gas injected vita the gas injection aperture.

As discussed above, the plasma processing apparatus can provide for bevel processing with advantages relative to prior tools. For instance, the plasma processing apparatus can have much lower cost relative to certain bevel etch apparatus because no electrostatic chuck is required to hold the substrate during processing. Moreover, no RF bias power is involved, meaning only one RF power source is required.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A plasma processing apparatus for processing a bevel portion of a semiconductor wafer, the plasma processing apparatus comprising:
a processing chamber;
a plasma chamber separated from the processing chamber by a separation grid;
an inductively coupled plasma source configured to generate a plasma in the plasma chamber;
a pedestal disposed within the processing chamber, the pedestal configured to support a semiconductor wafer;
wherein the separation grid has an edge portion and a blocking portion, the edge portion disposed above an edge portion of the semiconductor wafer when supported on the pedestal, wherein the edge portion of the separation grid has a plurality of holes configured to allow the passage of active radicals generated in the plasma to the processing chamber.

2. The plasma processing apparatus of claim 1, wherein the active radicals provide for treatment of a bevel portion of the semiconductor wafer.

3. The plasma processing apparatus of claim 1, wherein the blocking portion reduces the passage of ions and active radicals generated in the plasma to the processing chamber.

4. The plasma processing apparatus of claim 1, wherein the blocking portion comprises a solid portion of the separation grid.

5. The plasma processing apparatus of claim 1, wherein the edge portion extends a distance of about 30 mm or less from a perimeter of the separation grid.

6. The plasma processing apparatus of claim 1, wherein the separation grid has a gas injection aperture formed in a center portion of the separation grid, the gas injection aperture configured to allow the injection of a protective gas onto the semiconductor wafer to control a width of a bevel treatment process on the semiconductor wafer.

7. The plasma processing apparatus of claim 6, wherein the apparatus further comprises an insert, the insert having a peripheral portion and a center portion, the center portion extending a vertical distance past the peripheral portion, the center portion extending to the separation grid.

8. The plasma processing apparatus of claim 7, wherein the plasma processing apparatus has a first gas injection port to the plasma chamber and a second gas injection port for providing gas through the insert.

9. The plasma processing apparatus of claim 8, wherein the insert defines a gas channel from the second gas injection port to the gas injection aperture on the separation grid.

10. The plasma processing apparatus of claim 1, wherein the apparatus further comprises an aligning focus ring configured to assist positioning of the semiconductor wafer on the pedestal.

11. The plasma processing apparatus of claim 1, wherein the pedestal comprises a heat source for heating the semiconductor wafer.

12. The plasma processing apparatus of claim 1, wherein the pedestal is movable in a vertical direction to adjust a vertical position of the semiconductor wafer relative to the separation grid.

13. The plasma processing apparatus of claim 1, wherein the apparatus further comprises one or more movable lift pins configured to support the semiconductor wafer, the lift pins moveable in a vertical direction to adjust a vertical position of the semiconductor wafer relative to the separation grid.

14. A separation grid for a plasma processing apparatus having a processing chamber and a plasma chamber remote from the processing chamber, the separation grid having an edge portion and a blocking portion, wherein the edge portion has a plurality of holes configured to allow the passage of active radicals generated in the plasma to the processing chamber to treat the edge portion of the semiconductor wafer.

15. The separation grid of claim 14, wherein the blocking portion does not have any holes.

16. The separation grid of claim 14, wherein the blocking portion comprises a solid portion.

17. The separation grid of claim 14, wherein the edge portion extends a distance of about 30 mm or less from a perimeter of the separation grid.

18. The separation grid of claim 14, wherein the separation grid has a gas injection aperture formed in a center portion of the separation grid, the gas injection aperture configured to allow the injection of a protective neutral gas onto the semiconductor wafer to control a width of a bevel treatment process on the semiconductor wafer.

19. A method of treating a bevel portion of a semiconductor wafer in a plasma processing apparatus, the method comprising:
placing a semiconductor wafer having a bevel portion on a pedestal in a processing chamber of a plasma processing apparatus, the processing chamber being separated from a plasma chamber by a separation grid, the separation grid having an edge portion disposed over the edge of the semiconductor wafer and a center portion;
heating the semiconductor wafer using one or more heat sources in the pedestal;
generating a plasma in the plasma chamber by energizing an inductively coupled plasma source;
filtering one or more ions in the edge portion of the separation grid
providing active radicals through edge portion to treat the bevel portion of the semiconductor wafer; and
blocking ions and active radicals generated in the plasma with the blocking portion of the separation grid.

20. The method of claim 19, wherein the method comprises providing a gas through a gas injection aperture of the separation grid to a control a width of the bevel treatment process on the semiconductor wafer.
